(19) United States
(12) Patent Application Publication
(10) Pub. No.: US 2007/0128834 A1
(43) Pub. Date: Jun. 7, 2007

(54) Wafer dividing method

(75) Inventor: Masaru Nakamura, Tokyo (JP)

Correspondence Address: SMITH, GAMBRELL & RUSSELL, 1850 M STREET, N.W., SUITE 800, WASHINGTON, DC, 20036, US

(73) Assignee: Disco Corporation

(21) Appl. No.: 11/604,763

(22) Filed: Nov. 28, 2006

(30) Foreign Application Priority Data
Dec. 2, 2005 (JP) 2005-348957

(51) Int. Cl. H01L 21/00

(52) U.S. Cl. 438/460

(57) ABSTRACT

A method of dividing a wafer having devices which are formed in a plurality of areas sectioned by a plurality of dividing lines, along the dividing lines, comprising the steps of forming a deteriorated layer in the inside of the wafer along the dividing lines by applying a laser beam of a wavelength having permeability for the wafer; putting the rear surface of the wafer on the surface of an adhesive tape which is mounted on an annular frame, coated with an adhesive whose adhesive strength is reduced by applying ultraviolet radiation thereto, and shrinks by heating; dividing the wafer along the dividing lines by exerting external force to the wafer; reducing the adhesive strength of the adhesive by applying ultraviolet radiation to the adhesive tape; expanding the adhesive tape to widen the space between adjacent chips; and maintaining the space between adjacent chips by heating a shrink area between the inner peryphery of the annular frame and the area to which the wafer is affixed, of the adhesive tape.

### FIELD OF THE INVENTION

The present invention relates to a method of dividing a wafer having a plurality of dividing lines which are formed in a lattice pattern on the front surface and devices which are formed in a plurality of areas sectioned by the plurality of dividing lines into individual chips along the dividing lines.

### DESCRIPTION OF THE PRIOR ART

In the production process of a semiconductor device, a plurality of areas are sectioned by dividing lines called “streets” which are arranged in a lattice pattern on the front surface of a substantially disk-like semiconductor wafer, and a device such as IC or LSI is formed in each of the sectioned areas. Individual semiconductor chips are manufactured by cutting this semiconductor wafer along the dividing lines to divide it into the areas having each a device formed therein. An optical device wafer comprising a gallium nitride-based compound semiconductor laminated on the front surface of a sapphire substrate is also cut along predetermined dividing lines to be divided into individual optical devices such as light emitting diodes or laser diodes which are widely used in electric appliances.

Cutting along the dividing lines of the above semiconductor wafer or optical device wafer is generally carried out by a cutting machine called “dicer”. This cutting machine has a chuck table for holding a workpiece such as a semiconductor wafer or optical device wafer, a cutting means for cutting the workpiece held on the chuck table, and a cutting-feed means for moving the chuck table and the cutting means relative to each other. The cutting means comprises a rotary spindle, a cutting blade mounted on the spindle and a drive mechanism for rotary-driving the rotary spindle. The cutting blade comprises a disk-like base and an annular cutting-edge which is mounted on the side wall (outer peripheral portion) of the base and formed as thick as about 20 μm by fixing diamond abrasive grains having a diameter of about 3 μm to the base by electroforming.

Since a sapphire substrate, silicon carbide substrate, etc. have high Mohs hardness, however, cutting with the above cutting blade is not always easy. Since the cutting blade has a thickness of about 20 μm, the dividing lines for sectioning devices must have a width of about 50 μm. Therefore, in the case of a device measuring, for example, about 300 μm×300 μm, the area ratio of the dividing lines to the wafer becomes 14%, thereby reducing productivity.

As a means of dividing a plate-like workpiece such as a semiconductor wafer, Japanese Patent No. 3408805 discloses a laser processing method for applying a pulse laser beam of a wavelength having permeability for the workpiece with its focal point set to the inside of the area to be divided. In the dividing method making use of this laser processing technique, the workpiece is divided by applying a pulse laser beam of an infrared range having permeability for the workpiece from one side of the workpiece with its focal point set to the inside to continuously form a deteriorated layer in the inside of the workpiece along the dividing lines and exerting external force along the dividing lines whose strength has been reduced by the formation of the deteriorated layers.

To divide the semiconductor wafer along the dividing lines, the semiconductor wafer is divided in a state where it is put on the surface of an adhesive tape mounted on an annular frame so that the obtained chips do not fall apart. Therefore, when the wafer is divided by the dividing method disclosed by the above publication, there is no space between the chips and the chips closely adhere to one another, whereby adjacent chips are rubbed with each other during conveyance and consequently, damaged.

To solve this problem, the assignee company of the present invention proposes as Japanese patent application No. 2004-300384 a method of dividing a wafer, comprising the steps of putting a wafer having the above deteriorated layers on the surface of an adhesive tape which is mounted on an annular frame and shrinks by an external stimulus, dividing the wafer along the dividing lines where the deteriorated layer has been formed, then exerting an external stimulus to the shrink area between the inner periphery of the annular frame and the wafer affixing area of the adhesive tape to shrink the shrink area so as to expand the space between adjacent chips.

When the chips are to be picked up from the adhesive tape and die-bonded, after ultraviolet light is applied to the adhesive tape to reduce its adhesive strength, the chips are picked up from the adhesive tape. At this moment, there arises a problem that part of the adhesive of the adhesive tape sticks to the rear surfaces of the chip, thereby reducing the quality of the chips.

### SUMMARY OF THE INVENTION

It is an object of the present invention to provide a method of dividing a wafer having a plurality of dividing lines which are formed in a lattice pattern on the front surface and devices which are formed in a plurality of areas sectioned by the plurality of dividing lines, into individual chips along the dividing lines, wherein the individual chips can be held with a predetermined space therebetween and picked up without the adhesive sticking to the rear surfaces of the chips.

To attain the above object, according to the present invention, there is provided a method of dividing a wafer having a plurality of dividing lines which are formed in a lattice pattern on the front surface and devices which are formed in a plurality of areas sectioned by the plurality of dividing lines, into individual chips along the dividing lines, comprising:

a deteriorated layer forming step for forming a deteriorated layer in the inside of the wafer along the dividing lines by applying a laser beam of a wavelength having permeability for the wafer along the dividing lines;

a wafer supporting step for putting the rear surface of the wafer on the surface of an adhesive tape which is mounted on an annular frame, coated with an adhesive whose adhesive strength is reduced by applying ultraviolet radiation thereto, and shrinks by heating, after the deteriorated layer forming step;

a wafer dividing step for dividing the wafer into individual chips along the dividing lines where the deteriorated layer has been formed, by exerting external force to the wafer affixed to the adhesive tape;

an adhesive strength reducing step for reducing the adhesive strength of the adhesive by applying ultraviolet radiation to the adhesive tape to which the wafer has been affixed before or after the wafer dividing step;

a chips-spacing forming step for expanding the adhesive tape to widen the space between adjacent chips; and

a chips-spacing maintaining step for maintaining the space between adjacent chips by heating a shrink area between the inner periphery of the annular frame and the area to which the wafer has been affixed, of the adhesive tape to shrink it.

Since the step of reducing the adhesive strength of the adhesive has been carried out by applying ultraviolet radiation to the adhesive tape to which the wafer has been affixed before the chips-spacing forming step in the wafer dividing method of the present invention, the adhesive applied to the surface of the adhesive tape is cured, whereby the adhesive does not stick to the rear surfaces of the semiconductor chips and therefore, the quality of the chips is not reduced. Since the adhesive strength of the adhesive applied to the surface of the adhesive tape is reduced by carrying out the adhesive strength reducing step, individual chips can be easily picked up.

### BRIEF DESCRIPTION OF THE DRAWINGS

FIG. 1 is a perspective view of a semiconductor wafer to be divided into individual chips by the wafer dividing method of the present invention;

FIG. 2 is a perspective view showing a state of the semiconductor wafer shown in FIG. 1 having a protective member on the front surface;

FIG. 3 is a perspective view of the principal section of a laser beam processing machine for carrying out the deteriorated layer forming step in the wafer dividing method of the present invention;

FIGS. 4(a) and 4(b) are explanatory diagrams showing the deteriorated layer forming step in the wafer dividing method of the present invention;

FIG. 5 is a diagram showing a state where deteriorated layers are laminated in the inside of the semiconductor wafer in the deteriorated layer forming step shown in FIGS. 4(a) and 4(b);

FIG. 6 is an explanatory diagram showing the wafer supporting step in the wafer dividing method of the present invention;

FIG. 7 is an explanatory diagram showing the wafer dividing step in the wafer dividing method of the present invention;

FIG. 8 is a perspective view of a ultraviolet illuminator for carrying out the adhesive strength reducing step in the wafer dividing method of the present invention;

FIG. 9 is an explanatory diagram showing the adhesive strength reducing step in the wafer dividing method of the present invention;

FIG. 10 is a perspective view of a tape expanding apparatus for carrying out the chips-spacing forming step and the chips-spacing maintaining step in the wafer dividing method of the present invention;

FIG. 11 is a sectional view of the tape expanding apparatus shown in FIG. 10;

FIGS. 12(a) and 12(b) are explanatory diagrams showing the chips-spacing forming step in the wafer dividing method of the present invention; and

FIGS. 13(a) and 13(b) are explanatory diagrams showing the chips-spacing maintaining step in the wafer dividing method of the present invention.

### DETAILED DESCRIPTION OF THE PREFERRED EMBODIMENTS

Preferred embodiments of the wafer dividing method of the present invention will be described in detail hereinunder with reference to the accompanying drawings.

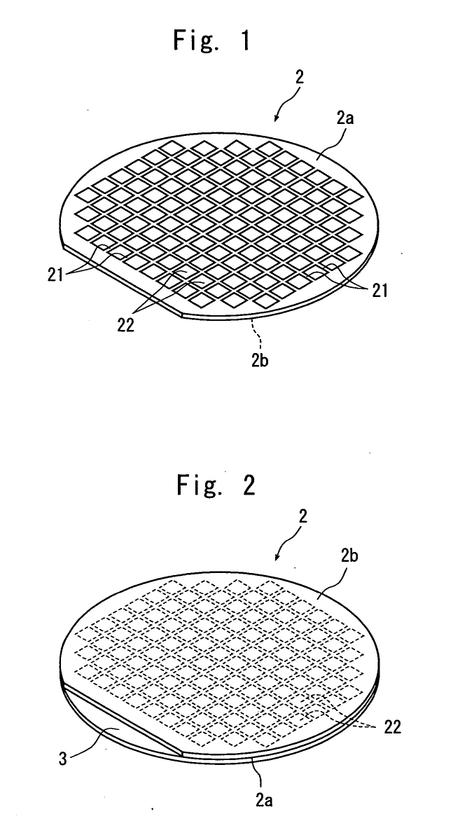

FIG. 1 is a perspective view of a semiconductor wafer as a wafer to be divided by the wafer dividing method of the present invention. The semiconductor wafer 2 shown in FIG. 1 is, for example, a silicon wafer having a thickness of 300 μm, and a plurality of dividing lines 21 are formed in a lattice pattern on the front surface 2a. A device 22 such as IC or LSI is formed in a plurality of areas sectioned by the plurality of dividing lines 21 on the front surface 2a of the semiconductor wafer 2. The method of dividing this semiconductor wafer 2 into individual semiconductor chips will be described hereinunder.

A protective member 3 is affixed to the front surface 2a of the above-described semiconductor wafer 2 as shown in FIG. 2 (protective member affixing step).

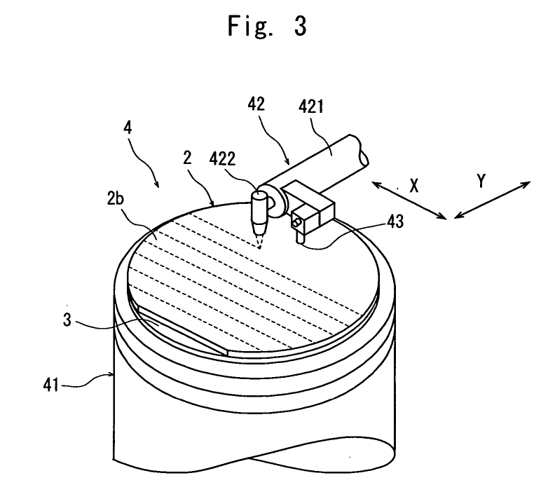

After the protective member 3 is affixed to the front surface 2a of the semiconductor wafer 2 by carrying out the above protective member affixing step, next comes the step of forming a deteriorated layer in the inside of the semiconductor wafer 2 along the dividing lines 21 by applying a pulse laser beam having permeability for a silicon wafer from the rear surface 2b of the semiconductor wafer 2 along the dividing lines 21 so as to reduce strength along the dividing lines 21. This deteriorated layer forming step is carried out by using a laser beam processing machine 4 shown in FIG. 3. The laser beam processing machine 4 shown in FIG. 3 comprises a chuck table 41 for holding a workpiece, a laser beam application means 42 for applying a laser beam to the workpiece held on the chuck table 41, and an image pick-up means 43 for picking up an image of the workpiece held on the chuck table 41. The chuck table 41 is designed to suction-hold the workpiece and to be moved in a processing-feed direction indicated by an arrow X and an indexing-feed direction indicated by an arrow Y in FIG. 3 by a moving mechanism that is not shown.

The above laser beam application means 42 has a cylindrical casing 421 arranged substantially horizontally. In the casing 421, there is installed a pulse laser beam oscillation means (not shown) which comprises a pulse laser beam oscillator composed of a YAG laser oscillator or YVO4 laser oscillator and a repetition frequency setting means. A condenser 422 for converging a pulse laser beam oscillated from the pulse laser beam oscillation means is attached to the end of the above casing 421.

An image pick-up means 43 mounted on the end portion of the casing 421 constituting the above laser beam application means 42 comprises an infrared illuminating means for applying infrared radiation to the workpiece, an optical system for capturing infrared radiation applied by the infrared illuminating means, and an image pick-up device (infrared CCD) for outputting an electric signal corresponding to infrared radiation captured by the optical system, in addition to an ordinary image pick-up device (CCD) for picking up an image with visible radiation in the illustrated embodiment. An image signal is supplied to a control means that is not shown.

The deteriorated layer forming step which is carried out by using the above laser beam processing machine 4 will be described with reference to FIGS. 3 to 5.

In this deteriorated layer forming step, the protective member 3 side of the semiconductor wafer 2 is first placed on the chuck table 41 of the laser beam processing machine 4, shown in FIG. 3 (therefore, the rear surface 2b of the semiconductor wafer 2 faces up), and the semiconductor wafer 2 is suction-held on the chuck table 41 by a suction means that is not shown. The chuck table 41 suction-holding the semiconductor wafer 2 is brought to a position right below the image pick-up means 43 by the moving mechanism that is not shown.

After the chuck table 41 is positioned right below the image pick-up means 43, alignment work for detecting the area to be processed of the semiconductor wafer 2 is carried out by the image pick-up means 43 and the control means that is not shown. That is, the image pick-up means 43 and the control means (not shown) carry out image processing such as pattern matching, etc. to align a dividing line 21 formed in a predetermined direction of the semiconductor wafer 2 with the condenser 422 of the laser beam application means 42 for applying a laser beam along the dividing line 21, thereby performing the alignment of a laser beam application position. The alignment of the laser beam application position is also carried out on dividing lines 21 formed on the semiconductor wafer 2 in a direction perpendicular to the above predetermined direction. Although the front surface 2a having the dividing lines 21 formed thereon of the semiconductor wafer 2 faces down at this point, as the image pick-up means 43 comprises an infrared illuminating means, an optical system for capturing infrared radiation and an image pick-up device (infrared CCD) for outputting an electric signal corresponding to the infrared radiation as described above, images of the dividing lines 21 can be picked up through the rear surface 2b.

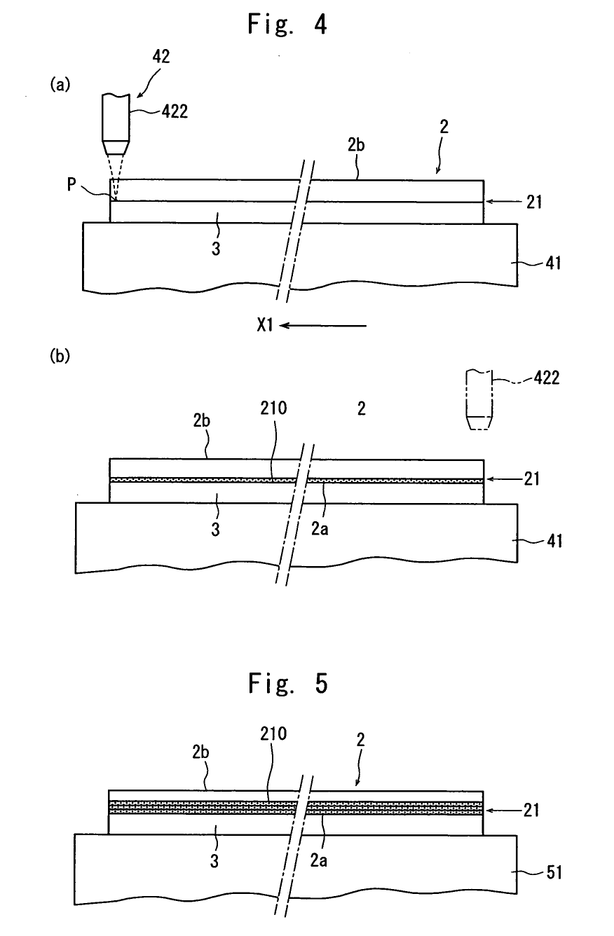

After the dividing line 21 formed on the semiconductor wafer 2 held on the chuck table 41 is detected and the alignment of the laser beam application position is carried out as described above, the chuck table 41 is moved to a laser beam application area where the condenser 422 of the laser beam application means 42 for applying a laser beam is located as shown in FIG. 4(a) to bring one end (left end in FIG. 4(a)) of the predetermined dividing line 21 to a position right below the condenser 422 of the laser beam application means 42. The chuck table 41, that is, the semiconductor wafer 2 is then moved in the direction indicated by the arrow X1 in FIG. 4(a) at a predetermined feed rate while a pulse laser beam having permeability for a silicon wafer is applied from the condenser 422. When the application position of the condenser 422 reaches the other end of the dividing line 21 as shown in FIG. 4(b), the application of the pulse laser beam is suspended and the movement of the chuck table 41, that is, the semiconductor wafer 2 is stopped. In this deteriorated layer forming step, the focal point P of the pulse laser beam is set to a position near the front surface 2a (undersurface) of the semiconductor wafer 2. As a result, a deteriorated layer 210 is exposed to the front surface 2a (undersurface) of the semiconductor wafer 2 and formed from the front surface 2a toward the inside. This deteriorated layer 210 is formed as a molten and re-solidified layer.

The processing conditions in the above deteriorated layer forming step are set as follows, for example.
Light source: LD excited Q switch Nd:YVO4 laser
Wavelength: pulse laser beam having a wavelength of 1,064 Pulse output: 10 μJ
Focal spot diameter: 1 μm
Repetition frequency: 100 kHz
Processing-feed rate: 100 mm/sec

When the semiconductor wafer 2 is thick, as shown in FIG. 5, the above-described deteriorated layer forming step is carried out several times by changing the focal point P stepwise so as to form a plurality of deteriorated layers 210. For example, as the thickness of the deteriorated layer formed once under the above processing conditions is about 50 μm, the above deteriorated layer forming step is carried out three times to form deteriorated layers 210 having a total thickness of 150 μm. In the case of a wafer 2 having a thickness of 300 μm, six deteriorated layers 210 maybe formed from the front surface 2a to the rear surface 2b along the dividing lines 21 in the inside of the semiconductor wafer 2. The above deteriorated layer 210 may be formed only in the inside of the semiconductor wafer 2 so as not to be exposed to the front surface 2a and the rear surface 2b.

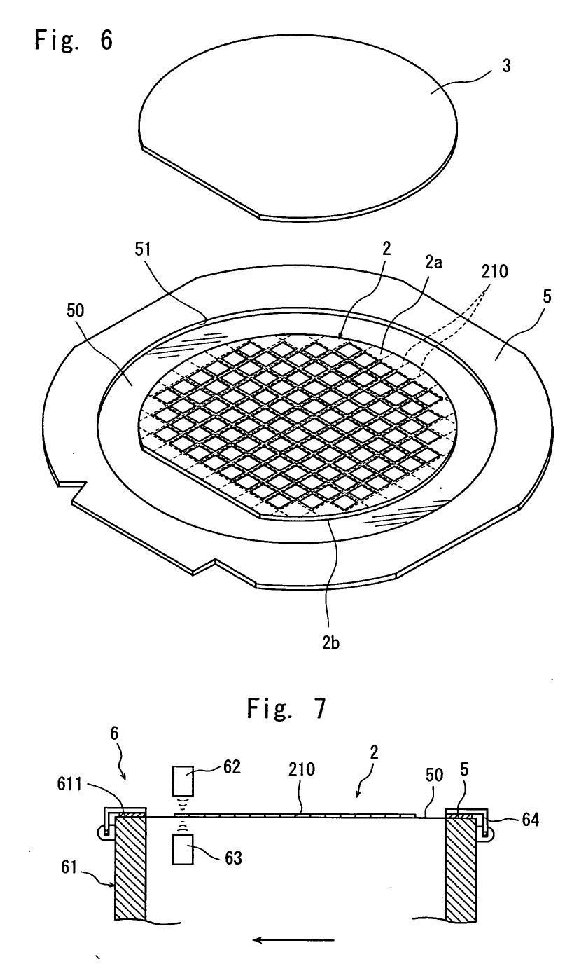

After the above deteriorated layer forming step is carried out along all the dividing lines 21 formed in the predetermined direction of the semiconductor wafer 2 as described above, the chuck table 41 is turned at 90° to carry out the above deteriorated layer forming step along dividing lines 21 formed in a direction perpendicular to the above predetermined direction. After the above deteriorated layer forming step is carried out along all the dividing lines 21 formed on the semiconductor wafer 2 as described above, next comes a wafer supporting step for putting the rear surface of the wafer on the surface of an adhesive tape which is mounted on an annular frame and whose adhesive strength is reduced by applying ultraviolet radiation thereto. That is, as shown in FIG. 6, the rear surface 2b of the semiconductor wafer 2 is put on the surface of the adhesive tape 50 whose peripheral portion is mounted on the annular frame 5 so as to cover its inner opening 51. Then, the protective member 3 is peeled off from the front surface 2a of the semiconductor wafer 2. The adhesive tape 50 is prepared by applying an adhesive whose adhesive strength is reduced by curing upon exposure to ultraviolet radiation to the surface of a 70 μm-thick sheet backing made of polyvinyl chloride (PVC). The sheet backing is elastic at normal temperature and shrinks by heat having a temperature higher than a predetermined temperature (for example, 70° C.). As the adhesive tape having the above characteristic properties may be used the D series tape manufactured and marketed by Lintec Corporation, the UC series tape manufactured and marketed by The Furukawa Electric Co., Ltd. and the FSL-N400 series tape manufactured and marketed by Sumitomo Bakelite Co., Ltd.

The above wafer supporting step is followed by the step of dividing the semiconductor wafer 2 into individual chips along the dividing lines 21 where the deteriorated layer 210 has been formed by exerting external force to the semiconductor wafer 2 put on the adhesive tape 50. In the illustrated embodiment, this wafer dividing step is carried out by using an ultrasonic dividing apparatus 6 shown in FIG. 7. The ultrasonic dividing apparatus 6 comprises a cylindrical base 61, a first ultrasonic oscillator 62 and a second ultrasonic oscillator 63. The cylindrical base 61 constituting the ultrasonic dividing apparatus 6 has a top surface as a placing surface 611 for placing the above annular frame 5, and the above annular frame 5 is placed on the placing surface 611 and fixed by clamps 64. This base 61 is constituted to be moved in a horizontal direction and in a direction perpendicular to the sheet in FIG. 7 and is constituted to be allowed to turn by a moving means that is not shown. The first ultrasonic oscillator 62 and the second ultrasonic oscillator 63 constituting the ultrasonic dividing apparatus 6 are opposed to each other in such a manner that the semiconductor wafer 2 supported to the annular frame 5 placed on the placing surface 611 of the cylindrical base 61 through the adhesive tape 50 is interposed between them and generate longitudinal waves (compressional waves) having a predetermined frequency.

To carry out the wafer dividing step by using the ultrasonic dividing apparatus 6 constituted as described above, the adhesive tape 50 side of the annular frame 5 supporting the semiconductor wafer 2 (the deteriorated layer 210 is formed along the dividing lines 21) through the adhesive tape 50 is placed on the placing surface 611 of the cylindrical base 61 and fixed by the clamps 64. Thereafter, the base 61 is operated by the moving means (not shown) to bring one end (left end in FIG. 7) of a predetermined dividing line 21 formed on the semiconductor wafer 2 at a position where ultrasonic waves act thereon from the first ultrasonic oscillator 62 and the second ultrasonic oscillator 63. The first ultrasonic oscillator 62 and the second ultrasonic oscillator 63 are then activated to generate longitudinal waves (compressional waves) having a frequency of, for example, 28 kHz and the base 61 is moved in the direction indicated by the arrow at a feed rate of, for example, 50 to 100 mm/sec. As a result, ultrasonic waves generated from the first ultrasonic oscillator 62 and the second ultrasonic oscillator 63 are applied to the front surface 2a and rear surface 2b of the semiconductor wafer 2 along the dividing line 21, whereby the semiconductor wafer 2 is divided along the dividing line 21 whose strength has been reduced by the formation of the deteriorated layer 210. After the wafer dividing step is carried out along the predetermined dividing line 21, the base 61 is moved (indexing-fed) a distance corresponding to the interval between the dividing lines 21 in the direction perpendicular to the sheet to carry out the above wafer dividing step. After the above wafer dividing step is carried out along all the dividing lines 21 extending in the predetermined direction, the base 61 is turned at 90° to carry out the above wafer dividing step along dividing lines 21 formed on the semiconductor wafer 2 in a direction perpendicular to the above predetermined direction, whereby the semiconductor wafer 2 is divided into individual chips 20. Since the rear surfaces of the obtained chips adhere to the adhesive tape 50, they do not fall apart and the state of the wafer is maintained.

The following dividing methods may be employed to carry out the wafer dividing step besides the above dividing method.

That is, a method in which the semiconductor wafer 2 (the deteriorated layer 210 is formed along the dividing lines 21) mounted on the adhesive tape 50 is placed on a soft rubber sheet and then, the top surface of the semiconductor wafer 2 is pressed with a roller to divide the semiconductor wafer 2 along the dividing lines 21 whose strength has been reduced by the formation of the deteriorated layers 210 may be employed. Alternatively, a method in which a pressing member is worked along the dividing lines 21 whose strength has been reduced by the formation of the deteriorated layers 210 or a method in which a heat shock is given by applying a laser beam along the dividing lines 21 whose strength has been reduced by the formation of the deteriorated layers 210 may be employed.

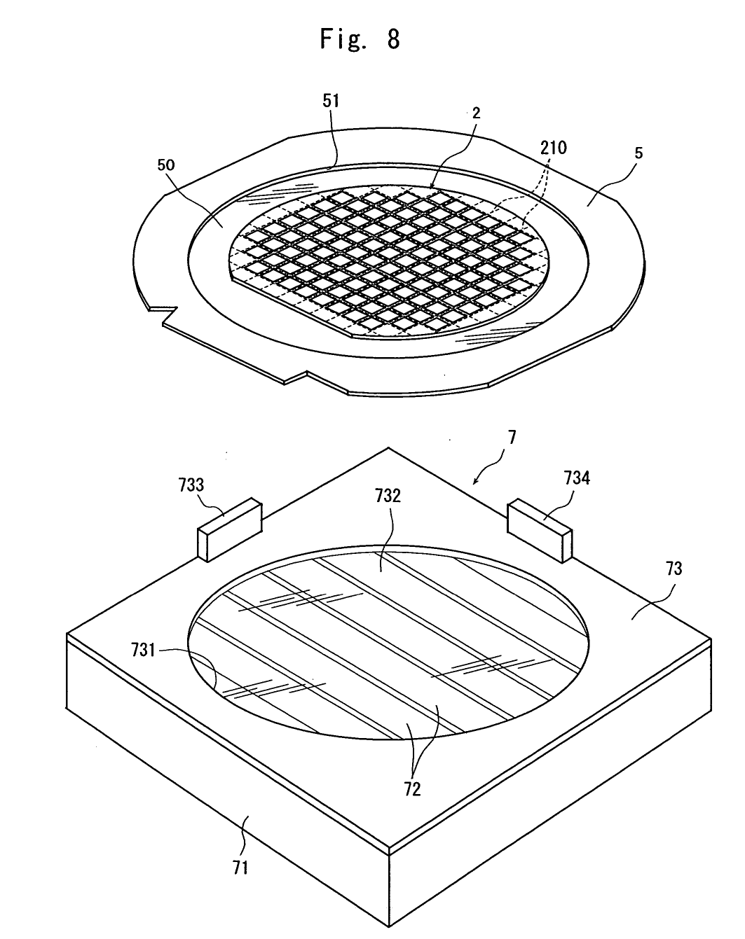

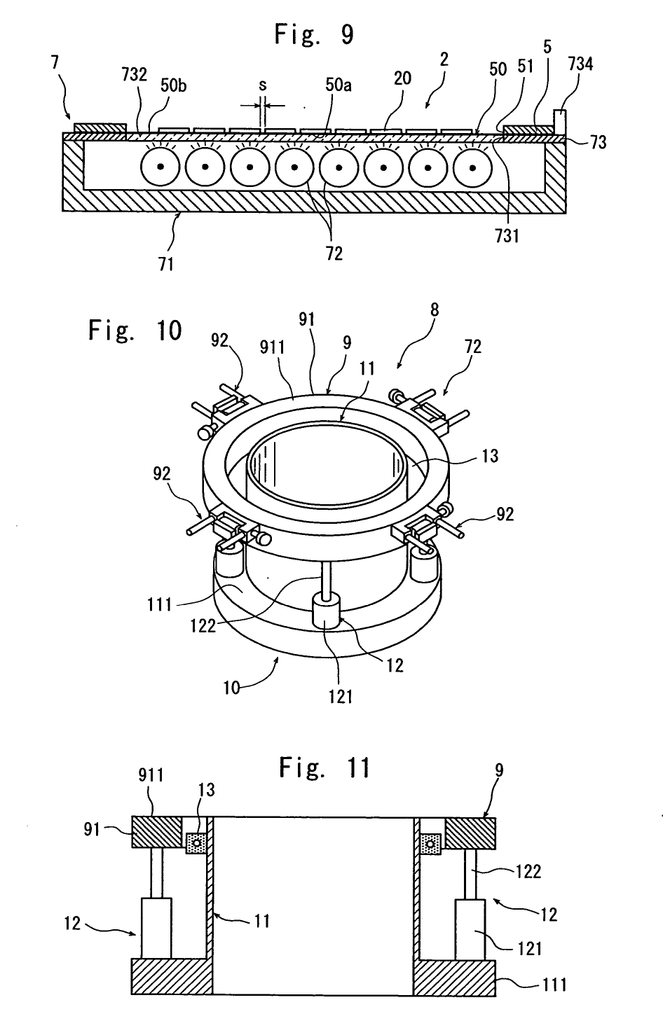

After the above wafer dividing step, next comes the step of reducing the adhesive strength of the adhesive tape 50 to which the semiconductor wafer 2 has affixed, by applying ultraviolet radiation thereto. This adhesive strength reducing step is carried out by using an ultraviolet illuminator 7 shown in FIG. 8 and FIG. 9 in the illustrated embodiment. The ultraviolet illuminator 7 shown in FIG. 8 and FIG. 9 comprises a substantially rectangular parallelepiped lamp housing 71, a plurality of ultraviolet lamps 72 installed in the lamp housing 71 and a frame holding plate 73 arranged on the top surface of the lamp housing 71. An opening 731 corresponding to the opening 51 of the annular frame 5 is formed in the frame holding plate 73, and transparent glass 732 is fitted in the opening 731. Two positioning members 733 and 734 for restricting the outer periphery of the annular frame 5 are provided on the top surface of the frame holding plate 73.

The annular frame 5 supporting the semiconductor wafer 2 (divided into individual semiconductor chips 20 along the dividing lines 21) through the adhesive tape 50 is placed on the frame holding plate 73 of the ultraviolet illuminator 7 constituted as described above. At this point, the annular frame 5 is positioned at a predetermined location by bringing the outer periphery of the annular frame 5 into contact with the two positioning members 733 and 734. After the annular frame 5 is positioned at the predetermined location of the frame holding plate 73, the opening 731 formed in the frame holding plate 73 corresponds to the opening 51 of the annular frame 5, as shown in FIG. 9. Then, the ultraviolet lamps 72 are turned on. By turning on the ultraviolet lamps 72, ultraviolet radiation is applied to the adhesive tape 50 mounted on the annular frame 5 through the transparent glass 732. As a result, the adhesive coated onto the surface of the adhesive tape 50 is cured to reduce its adhesive strength.

The above adhesive strength reducing step may be carried out before the above wafer dividing step.

After the above adhesive strength reducing step, next comes the chips-spacing forming step for widening the space between adjacent chips 20 by expanding the adhesive tape 50 and the chips-spacing maintaining step for maintaining the space between adjacent chips by heating the shrink area between the inner periphery of the annular frame 5 and the area to which the semiconductor wafer 2 has affixed, of the adhesive tape 50 to shrink it. This chips-spacing forming step and the chips-spacing maintaining step are carried out by using a tape expanding apparatus 8 shown in FIG. 10 and FIG. 11 in the illustrated embodiment.

FIG. 10 is a perspective view of the tape expanding apparatus 8, and FIG. 11 is a sectional view of the tape expanding apparatus 8 shown in FIG. 10. The tape expanding apparatus 8 in the illustrated embodiment comprises a frame holding means 9 for holding the above annular frame 5 and a tension application means 10 for expanding the adhesive tape 50 mounted on the above annular frame 5. The frame holding means 9 comprises an annular frame holding member 91 and four clamps 92 as fixing means arranged around the frame holding member 91, as shown in FIG. 10 and FIG. 11. The top surface of the frame holding member 91 forms a placing surface 911 for placing the annular frame 5, and the annular frame 5 is placed on this placing surface 911. The annular frame 5 placed on the placing surface 911 of the frame holding member 91 is fixed on the frame holding member 91 by the clamps 92.

The above tension application means 10 comprises an expansion drum 11 arranged within the above annular frame holding member 91. This expansion drum 11 has an outer diameter smaller than the diameter of the opening 51 of the annular frame 5 and an inner diameter larger than the diameter of the semiconductor wafer 2 put on the adhesive tape 50 mounted on the annular frame 5. The expansion drum 11 has a support flange 111 at the lower end. The tension application means 10 in the illustrated embodiment comprises a support means 12 capable of moving the above annular frame holding member 91 in the vertical direction (axial direction). This support means 12 comprises a plurality (4 in the illustrated embodiment) of air cylinders 121 installed on the above support flange 111, and their piston rods 122 are connected to the undersurface of the above annular frame holding member 91. The support means 12 comprising the plurality of air cylinders 121 moves the annular frame holding member 91 in the vertical direction between a standard position where the placing surface 911 of the annular frame holding member 91 becomes substantially flush with the upper end of the expansion drum 11 and an expansion position where the placing surface 911 is positioned below the upper end of the expansion drum 11 by a predetermined distance.

The illustrated tape expanding apparatus 8 has an annular infrared heater 13 as a heating means mounted on the outer wall of the upper portion of the above expansion drum 11. This infrared heater 13 heats the shrink area between the inner periphery of the opening 51 of the annular frame 5 and the semiconductor wafer 2 of the adhesive tape 50 mounted on the annular frame 5 held on the above frame holding means 9.

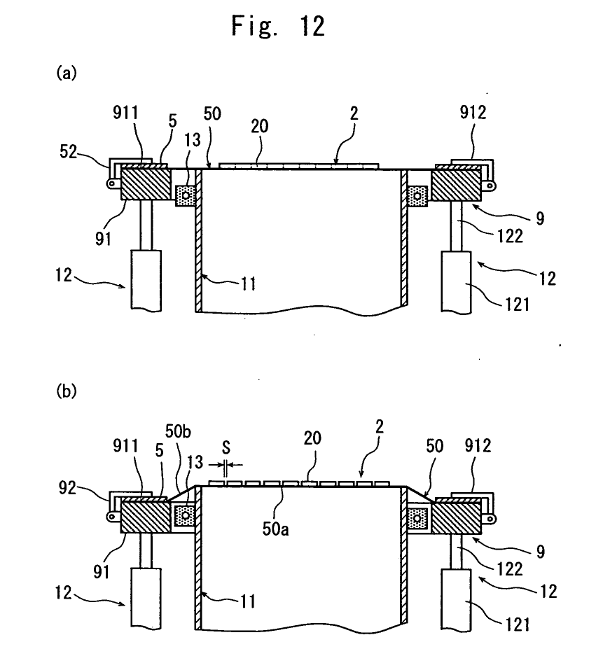

The chips-spacing forming step which is carried out by using the tape expanding apparatus 8 constituted as described above will be described with reference to FIGS. 12(a) and 12(b). That is, the annular frame 5 supporting the semiconductor wafer 2 (divided into individual chips 20 along the dividing lines 21) through the adhesive tape 50 as shown in FIG. 6 is placed on the placing surface 911 of the annular frame holding member 91 constituting the frame holding means 9 and fixed on the annular frame holding member 91 by the clamps 92 as shown in FIG. 12(a). At this point, the annular frame holding member 91 is situated at the standard position shown in FIG. 12(a).

Thereafter, the annular frame holding member 91 is lowered to the expansion position shown in FIG. 12(b) by activating the plurality of air cylinders 121 as the support means 12 constituting the tension application means 10. Therefore, the annular frame 5 fixed on the placing surface 911 of the frame holding member 91 is also lowered, whereby the adhesive tape 50 mounted on the annular frame 5 comes into contact with the upper edge of the expansion drum 11 to be expanded as shown in FIG. 12(b). As a result, tensile force works radially on the semiconductor wafer 2 put on the adhesive tape 50 and therefore, the area 50a to which the semiconductor wafer 2 has affixed is also expanded, thereby forming the space S between adjacent individual semiconductor chips 20.

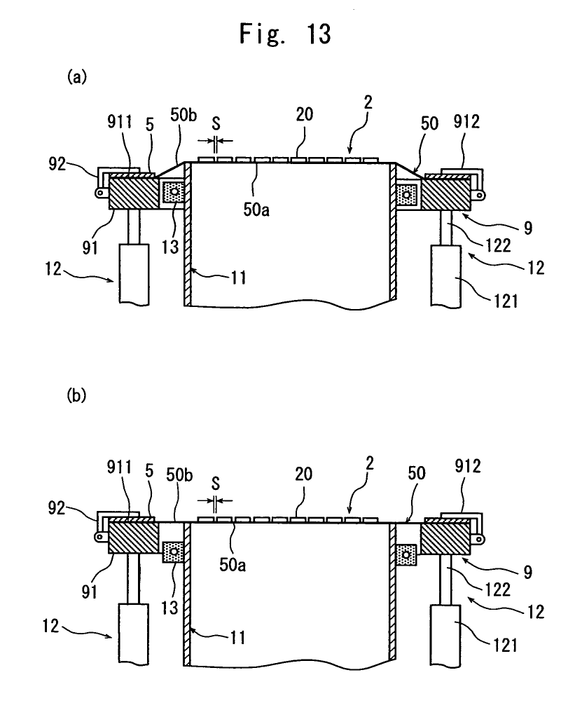

After the above-described chips-spacing forming step, next comes the step of maintaining the space between adjacent chips by heating the shrink area between the inner periphery of the annular frame 5 and the area to which the semiconductor wafer 2 has affixed, of the adhesive tape 50 to shrink it. This chips-spacing maintaining step is carried out by turning on the infrared heater 13 in a state where the above chips-spacing forming step has been carried out, as shown in FIG. 13(a). As a result, the shrink area 50b between the inner periphery of the opening 51 of the annular frame 5 and the area 50a to which the semiconductor wafer 2 has affixed, of the adhesive tape 50 is heated and shrunk by infrared radiation irradiated from the infrared heater 13. In line with this shrinking function, the plurality of cylinders 121 as the support means 12 constituting the tension application means 10 are activated to move up the annular frame holding member 91 to the standard position shown by FIG. 13(b). The heating temperature of the adhesive tape 50 by the above infrared heater 13 is suitably 70 to 100° C., and the heating time is 5 to 10 seconds. A slack in the adhesive tape 50 expanded by the above chips-spacing forming step is removed by shrinking the above shrink area 50b of the adhesive tape 50. Therefore, the space S formed between adjacent semiconductor chips 20 separated from each another in the above chips-spacing forming step is maintained.

After the chips-spacing maintaining step, the semiconductor wafer 2 separated into individual semiconductor chips 20 is carried to the next pick-up step in a state where it has been affixed to the adhesive tape 50 mounted on the annular frame 5. Since the space S is maintained between adjacent individual semiconductor chips 20 in the above chips-spacing maintaining step at this point, the adjacent chips are not rubbed with each other during conveyance, thereby making it possible to prevent the chips from being damaged by rubbing. In the pick-up step, as the adhesive strength of the adhesive tape 50 exposed to ultraviolet radiation in the above adhesive strength reducing step is reduced, the individual semiconductor chips 20 can be easily picked up.

Since the adhesive strength reducing step for reducing the adhesive strength of the adhesive tape 50 by applying ultraviolet radiation to the adhesive tape 50 to which the semiconductor wafer 2 has affixed is carried out before the chips-spacing forming step in the illustrated embodiment as described above, the adhesive applied to the surface of the adhesive tape 50 is cured, thereby preventing the sticking of the adhesive to the rear surfaces of the semiconductor chips 20 and a reduction in the quality of the chips.

What is claimed is:

1. A method of dividing a wafer having a plurality of dividing lines which are formed in a lattice pattern on the front surface and devices which are formed in a plurality of areas sectioned by the plurality of dividing lines, into individual chips along the dividing lines, comprising the steps of:
a deteriorated layer forming step for forming a deteriorated layer in the inside of the wafer along the dividing lines by applying a laser beam of a wavelength having permeability for the wafer along the dividing lines;
a wafer supporting step for putting the rear surface of the wafer on the surface of an adhesive tape which is mounted on an annular frame, coated with an adhesive whose adhesive strength is reduced by applying ultraviolet radiation thereto, and shrinks by heating, after the deteriorated layer forming step;
a wafer dividing step for dividing the wafer into individual chips along the dividing lines where the deteriorated layer has been formed, by exerting external force to the wafer affixed to the adhesive tape;
an adhesive strength reducing step for reducing the adhesive strength of the adhesive by applying ultraviolet radiation to the adhesive tape to which the wafer has been affixed before or after the wafer dividing step;
a chips-spacing forming step for expanding the adhesive tape to widen the space between adjacent chips; and
a chips-spacing maintaining step for maintaining the space between adjacent chips by heating a shrink area between the inner periphery of the annular frame and the area to which the wafer has been affixed, of the adhesive tape to shrink it.
